(19) United States
(12) Patent Application Publication
(10) Pub. No.: US 2024/0282771 A1
(43) Pub. Date: Aug. 22, 2024

(54) 3D U-SHAPED NANOSHEET DEVICE

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 18/172,595

(22) Filed: Feb. 22, 2023

(51) Int. Cl. H01L 27/092; H01L 21/822; H01L 21/8238; H01L 29/06; H01L 29/417; H01L 29/423; H01L 29/66; H01L 29/775

(52) U.S. Cl. CPC H01L 27/0922; H01L 21/8221; H01L 21/823807; H01L 21/823814; H01L 21/823871; H01L 21/823878; H01L 29/0673; H01L 29/41733; H01L 29/42392; H01L 29/66439; H01L 29/66545; H01L 29/775

(57) ABSTRACT

A method of fabricating a semiconductor device includes forming a patterned stack of layers including at least one lower active layer for forming a lower transistor and at least one upper active layer for forming an upper transistor stacked on the lower transistor. A dummy gate is formed surrounding a gate portion of each of the lower active layers and each of the upper active layers in the patterned stack, and the source-drain portions of the lower active layers and the upper active layers are doped. Source-drain connections to doped source-drain portions of the lower active layers and the upper active layers are formed. The dummy gate of the lower active layers and the upper active layers is replaced with a gate-all-around (GAA) structure to form the lower transistor and the upper transistor.

### FIELD OF THE INVENTION

The present disclosure generally relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

### SUMMARY

The present disclosure is directed towards a semiconductor device and a method to fabricate a semiconductor device.
Aspect (1) provides a method of fabricating a semiconductor device, including forming a patterned stack of layers including at least one lower active layer for forming a lower transistor and at least one upper active layer for forming an upper transistor stacked on the lower transistor. A dummy gate is formed surrounding a gate portion of each of the lower active layers and each of the upper active layers in the patterned stack, and the source-drain portions of the lower active layers and the upper active layers are doped. Source-drain connections to doped source-drain portions of the lower active layers and the upper active layers are formed. The dummy gate of the lower active layers and the upper active layers is replaced with a gate-all-around (GAA) structure to form the lower transistor and the upper transistor.
Aspect (2) includes the method of aspect (1), wherein the forming a patterned stack includes forming a stack of alternating layers of active material and sacrificial material.
Aspect (3) includes the method of aspect (2), wherein the forming a stack includes forming at least two lower active layers for forming a multichannel lower transistor and at least two upper active layers for forming a multichannel upper transistor.
Aspect (4) includes the method of aspect (2), wherein the stack of alternating layers includes a silicon layer for each layer of active material; and a silicon germanium layer for each layer of sacrificial material.
Aspect (5) includes the method of aspect (4), wherein the forming a dummy gate includes removing sacrificial material from above and below the gate portion of each of the lower active layers and each of the upper active layers in the patterned stack; and replacing the removed sacrificial material with dummy gate material.
Aspect (6) includes the method of aspect (2), wherein the doping source-drain portions includes doping the lower active layers with a first doping material and doping the upper active layers with a second doping material, the first and second doping materials being different dopants selected from n-type dopants and p-type dopants such that the lower transistor and the upper transistor are complementary transistors.
Aspect (7) includes the method of aspect (6), further including forming a protective liner on the upper active layers, exposing the source-drain portions of the lower active layers, and doping the source-drain portions of the lower active layers with the first doping material while the upper active layers are protected by the protective liner.
Aspect (8) includes the method of aspect (7), further including after doping the source-drain portions of the lower active layers, forming a protective fill on the lower active layers, exposing the source-drain portions of the upper active layers, and doping the source-drain portions of the upper active layers with the second doping material while the lower active layers are protected by the protective fill.
Aspect (9) includes the method of aspect (8), further including forming a source-drain isolation structure between the lower active layers and the upper active layers after doping the source-drain portions of the lower active layers and before doping the source-drain portions of the upper active layers.
Aspect (10) includes the method of aspect (1), wherein the forming source-drain connections includes etching an opening to expose a contact part of each of the doped source-drain portions of the lower active layers and the upper active layers; and filling each opening with a connection metal fill such that each metal fill forms a contact interface where the metal fill contacts a respective contact part of the doped source-drain portions.
Aspect (11) includes the method of aspect (10), further including annealing each interface portion to form a silicide contact between each metal fill and a respective doped source-drain portion.
Aspect (12) includes the method of aspect (1), wherein the forming source-drain connections includes forming lower source-drain connections to the lower active layers before forming upper source-drain connections to the upper active layers.
Aspect (13) includes the method of aspect (1), wherein the replacing the dummy gate includes etching the dummy gate material to expose a respective gate portion of each of the lower active layers and the upper active layers, selectively depositing a gate dielectric layer on each exposed gate portion; and forming a gate metal layer on each gate dielectric layer.
Aspect (14) includes the method of aspect (13), further including forming a protective liner on the upper active layers, exposing the gate portions of the lower active layers; and forming the lower GAA structure around the exposed lower active layers while the upper active layers are protected by the protective liner.
Aspect (15) includes the method of aspect (14), further including after forming the lower GAA structure on the gate portions of the lower active layers, forming a protective fill on the lower active layers, exposing the gate portions of the upper active layers, and forming the upper GAA structure around the exposed upper active layers while the lower active layers are protected by the protective liner.
Aspect (16) includes the method of aspect (15), further including forming a gate isolation structure between the lower active layers and the upper active layers after forming the GAA structure around the gate portions of the lower active layers and before forming the GAA structure on the gate portions of the upper active layers.
Aspect (17) provides a semiconductor device including a substrate including a working surface; and stacked complementary transistors formed in the substrate. Each transistor includes a complex channel structure which is horizontally arranged with respect to the working surface. The complex channel structure includes a main portion extending in a main direction along the working surface, and tail portions each connected to a respective end of the main portion and extending along the working surface in a tail direction which is different from the main direction, a distal end of each tail including a source S-D end such that the S-D ends are offset from the main portion of the complex channel structure. A gate all around (GAA) structure is formed around only the main portion of the complex channel structure between the tail portions, and S-D contacts formed on respective S-D ends of the complex channel structure such that the S-D contacts are offset from the GAA structure.
Aspect (18) includes the semiconductor device of aspect (17), wherein each tail portion extends along a direction substantially perpendicular to the main portion.
Aspect (19) includes the semiconductor device of aspect (17), wherein the S/D contacts include metal and silicide.
Aspect (20) includes the semiconductor device of aspect (17), wherein the complex channel structure is U-shaped in a plane parallel to the working surface of the substrate.

### BRIEF DESCRIPTION OF THE DRAWINGS

Various embodiments of this disclosure that are proposed as examples will be described in detail with reference to the following figures, wherein like numerals reference like elements, and wherein:

FIG. 1A is a top plane view of an intermediate structure in a process for manufacturing a complex channel transistor, and FIG. 1B is a sectional view of the intermediate structure in accordance with an example embodiment of the disclosed invention.

FIG. 1C is a materials legend for the drawings.

FIG. 2A is a top plane view of an intermediate structure in a process for manufacturing a complex channel transistor, and FIGS. 2B and 2C are sectional views of the intermediate structure in accordance with an example embodiment of the disclosed invention.

FIG. 3A is a top plane view of an intermediate structure in a process for manufacturing a complex channel transistor, and FIGS. 3B and 3C are sectional views of the intermediate structure in accordance with an example embodiment of the disclosed invention.

FIG. 4A is a top plane view of an intermediate structure in a process for manufacturing a complex channel transistor, and FIGS. 4B and 4C are sectional views of the intermediate structure in accordance with an example embodiment of the disclosed invention.

FIG. 5A is a top plane view of an intermediate structure in a process for manufacturing a complex channel transistor, FIGS. 5B, 5C and 5D are sectional views and 5E is a perspective view of the intermediate structure in accordance with an example embodiment of the disclosed invention.

FIG. 6A is a top plane view of an intermediate structure in a process for manufacturing a complex channel transistor, and FIGS. 6B, 6C and 6D are sectional views and 6E is a perspective view of the intermediate structure in accordance with an example embodiment of the disclosed invention.

FIG. 7A is a top plane view of an intermediate structure in a process for manufacturing a complex channel transistor, and FIGS. 7B, 7C and 7D are sectional views and 7E is a perspective view of the intermediate structure in accordance with an example embodiment of the disclosed invention.

FIG. 8A is a top plane view of an intermediate structure in a process for manufacturing a complex channel transistor, and FIGS. 8B, 8C and 8D are sectional views of the intermediate structure in accordance with an example embodiment of the disclosed invention.

FIG. 9A is a top plane view of an intermediate structure in a process for manufacturing a complex channel transistor, FIGS. 9B, 9C and 9D are sectional views and 9E is a perspective view of the intermediate structure in accordance with an example embodiment of the disclosed invention.

FIG. 10A is a top plane view of an intermediate structure in a process for manufacturing a complex channel transistor, FIGS. 10B, 10C and 10D are sectional views of the intermediate structure in accordance with an example embodiment of the disclosed invention.

FIG. 11A is a top plane view of an intermediate structure in a process for manufacturing a complex channel transistor, and FIGS. 11B and 11C are sectional views of the intermediate structure in accordance with an example embodiment of the disclosed invention.

FIG. 12A is a top plane view of an intermediate structure in a process for manufacturing a complex channel transistor, FIGS. 12B and 12C are sectional views and 12D is a perspective view of the intermediate structure in accordance with an example embodiment of the disclosed invention.

FIG. 13A is a top plane view of an intermediate structure in a process for manufacturing a complex channel transistor, and FIGS. 13B and 13C are sectional views of the intermediate structure in accordance with an example embodiment of the disclosed invention.

FIG. 14A is a top plane view of an intermediate structure in a process for manufacturing a complex channel transistor, and FIGS. 14B, 14C, 14D and 14E are sectional views of the intermediate structure in accordance with an example embodiment of the disclosed invention.

FIG. 15A is a top plane view of an intermediate structure in a process for manufacturing a complex channel transistor, and FIGS. 15B, 15C, 15D and 15E are sectional views of the intermediate structure in accordance with an example embodiment of the disclosed invention.

FIG. 16A is a top plane view of an intermediate structure in a process for manufacturing a complex channel transistor, and FIGS. 16B, 16C, 16D and 16E are sectional views of the intermediate structure in accordance with an example embodiment of the disclosed invention.

FIG. 17A is a top plane view of an intermediate structure in a process for manufacturing a complex channel transistor, and FIGS. 17B, 17C, 17D and 17E are sectional views of the intermediate structure in accordance with an example embodiment of the disclosed invention.

FIG. 18A is a top plane view of an intermediate structure in a process for manufacturing a complex channel transistor, and FIGS. 18B, 18C and 18D are sectional views of the intermediate structure in accordance with an example embodiment of the disclosed invention.

FIG. 19A is a top plane view of an intermediate structure in a process for manufacturing a complex channel transistor, and FIGS. 19B, 19C and 19D are sectional views of the intermediate structure in accordance with an example embodiment of the disclosed invention.

FIG. 20A is a top plane view of an intermediate structure in a process for manufacturing a complex channel transistor, and FIGS. 20B, 20C and 20D are sectional views of the intermediate structure in accordance with an example embodiment of the disclosed invention.

FIG. 21A is a top plane view of an intermediate structure in a process for manufacturing a complex channel transistor, and FIGS. 21B, 21C and 21D are sectional views of the intermediate structure in accordance with an example embodiment of the disclosed invention.

FIG. 22A is a top plane view of an intermediate structure in a process for manufacturing a complex channel transistor, FIGS. 22B, 22C and 22D are sectional views and 22E is a perspective view of the intermediate structure in accordance with an example embodiment of the disclosed invention.

### DETAILED DESCRIPTION OF EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein in reference to various fabrication methods have been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

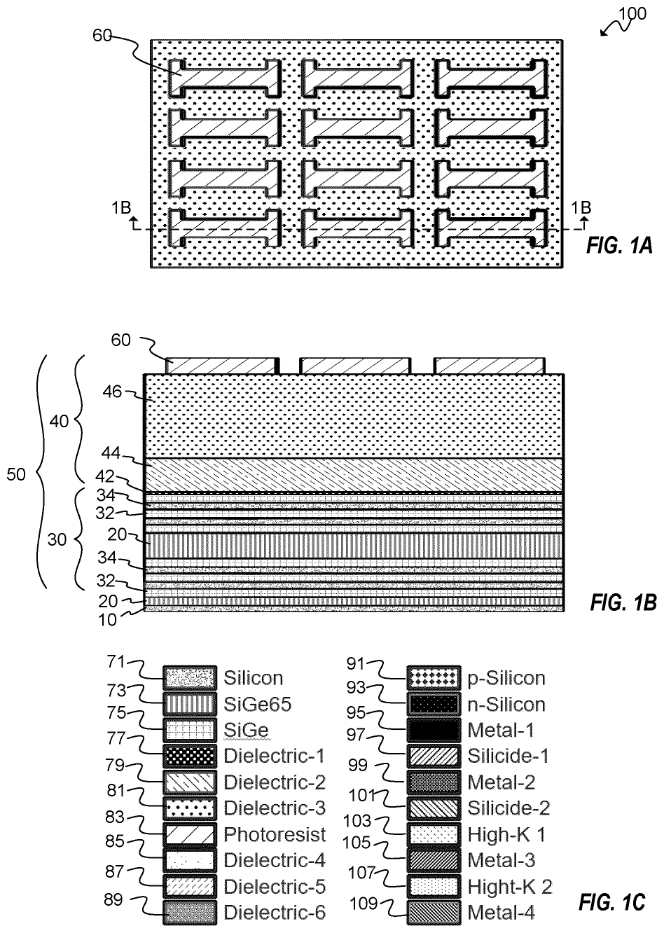

FIGS. 1A and 1B illustrate a structure 100 in which a patterned photoresist mask 60 is provided on an initial stack 50 formed on a substrate 10. FIG. 1A is a top plane view of the structure 100 and FIG. 1B is side view at section 1B-1B of the structure 100. The initial stack includes a dummy isolation layer 20, a stack of semiconductor layers 30, and a stack of dielectric layers 40 provided in sequence on the substrate 10. In the example embodiment of FIGS. 1A and 1B, the dummy isolation layer 20 is an epi-grown SiGe65 layer on top of Si substrate 10. The semiconductor layers 30 of this example are epi-grown in a sequence of alternating SiGe layers 32 and Si layers 34 layers two times followed by another dummy isolation layer 20 with thickness variation as shown in cross-sectional image 1B. The SiGe layer 32 and Si layer 30 sequence is repeated two times again, and another SiGe layer 32 is provided to finish the stack 30. Then the stack of dielectric layers 40 is formed to include layers having different etch selectivity from each other. In the example embodiment, the Si layers provide active material for forming the channel and source-drain (S-D) of a transistor, while the SiGe and SiGe65 layers provide sacrificial material used for forming other elements such as the gate of the transistors, isolation structures etc. The photoresist is patterned with a Mesa mask 60. A protective layer 42 of dielectric-1, followed by hard mask layer 44 of dielectric-2, and a top coating for a masking layer 46 of dielectric-3. An example of dielectric-1 is a protective oxide, an example of dielectric-2 is a nitride hard mask and a protecting top layer as per etch selectivity.

The example materials of FIGS. 1A and 1B are depicted throughout the drawings by way of material patterns shown in the legend 70 of FIG. 1C. In the legend, pattern 71 is Si, pattern 73 is SiGe65, pattern 75 is SiGe, pattern 77 is dielectric-1, pattern 79 is dielectric-2, pattern 81 is dielectric-3, pattern 83 is photoresist, pattern 85 is dielectric-4, pattern 87 is dielectric-5, pattern 89 is dielectric-6, pattern 91 is n-doped Si, pattern 93 is metal-1, pattern 95 is silicide, pattern 97 is high-k material, pattern 99 is metal-2, pattern 101 is silicide-2, pattern 103 is highK-1, pattern 105 is metal-3, pattern 107 highK-2 and pattern 109 is metal-4.

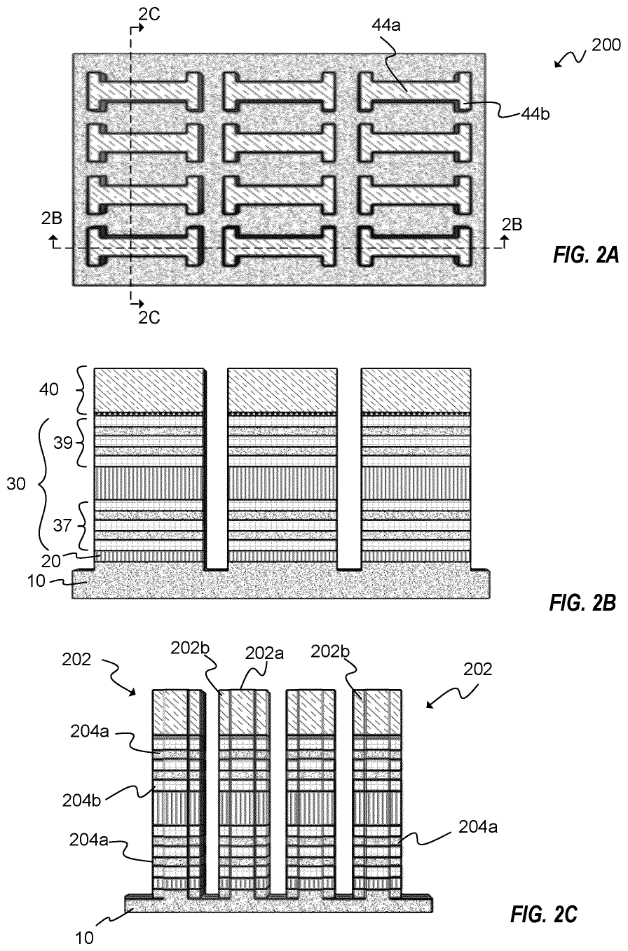

FIGS. 2A, 2B and 2C show a structure 200 after pattern etching the initial stack 50 with photoresist mask 60. FIG. 2A is a top plane view of the structure 200, FIG. 2B is side view at section 2B-2B, and FIG. 2C is a side view at section 2C-2C of the structure 200. This convention of providing section line labels that correspond to the figure number of the associated section view is used throughout this disclosure. The mask is a Mesa nanosheet mask used to etch the initial stack 50 all the way to Si substrate 10 step-by-step. As seen from the top view 2A, the patterned hard mask 44 includes a main portion 44a and tail portions 44b. The resulting etched structure includes patterned stacks 202 in the shape of the mask pattern with a main portion 202a and tail portions 202b. The patterned stacks 202 include patterned channel structures or nanosheets of active material having a main channel portion 204a and tail channel portions 204b.

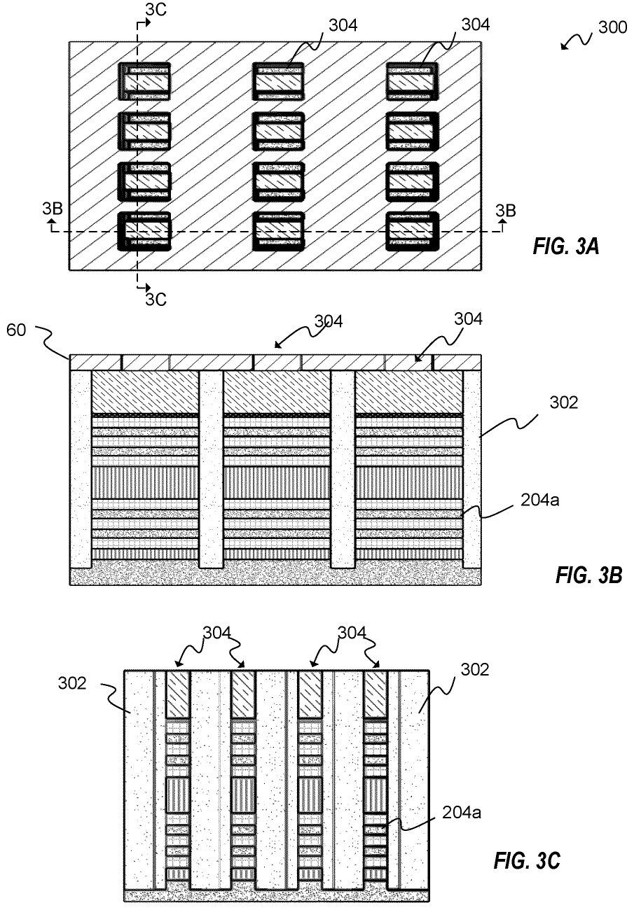

FIGS. 3A, 3B and 3C show a structure 300 after forming dummy gate openings 304. In one example process for forming dummy gate openings 304, the structure 200 is filled with fill material 302 of dielectric-4 and chemical mechanical polished (CMP). A photoresist dummy gate mask 60 is used to etch dummy gate openings 304 in the dielectric-4 directionally down to the substrate 10. The openings 304 expose sides of the main portion 202a of the patterned stack 202.

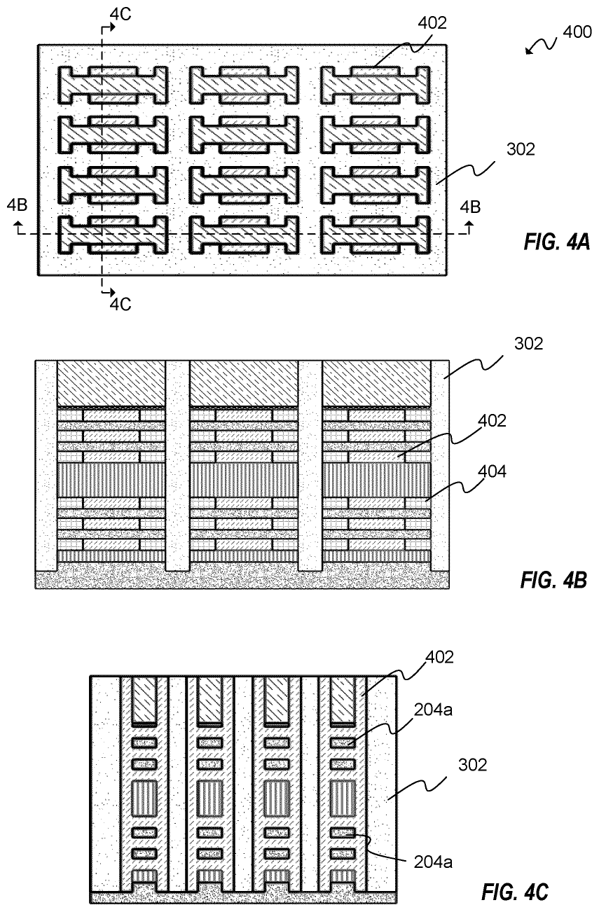

FIGS. 4A, 4B and 4C show a structure 400 after replacing sacrificial SiGe material from a main portion 202a of the patterned stack 202 with dummy gate material 402. An example process includes etching exposed parts of the SiGe layers and depositing a fill of dielectric-5 as dummy gate 402, and CMP to protect the gate area (dummy gate). This also defines the inner spacer area 404 for doping, and the channel area to be surrounded by the gate all around (GAA) structure.

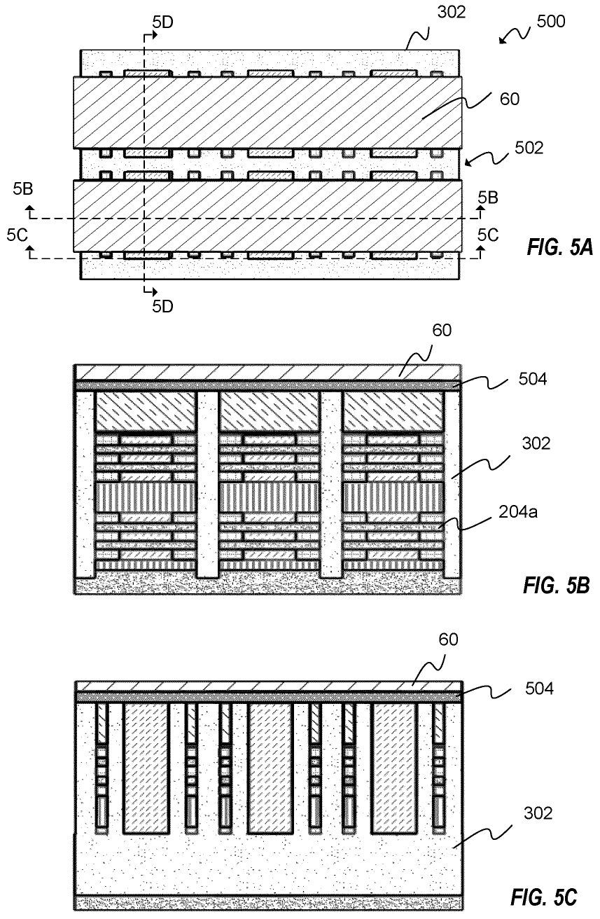

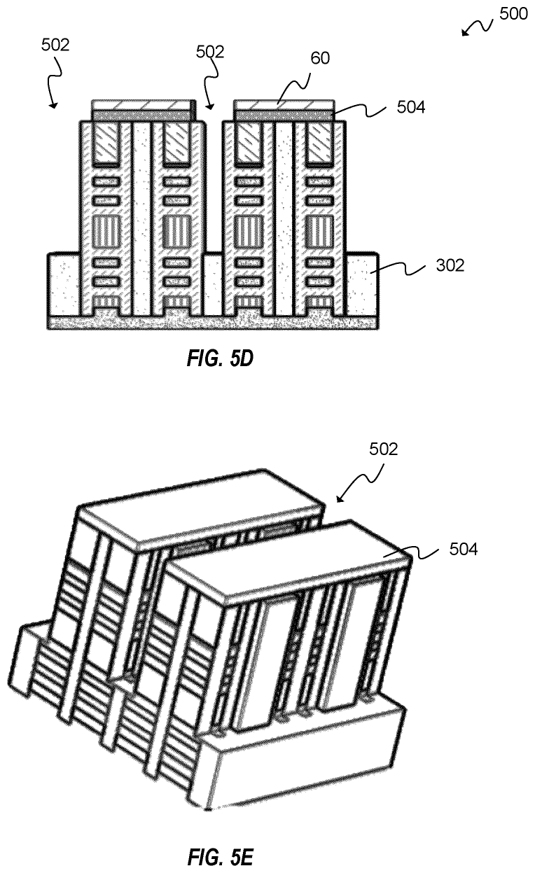

FIGS. 5A, 5B, 5C and 5D show a structure 500 after patterning with a complementary doping mask. In one example process, a patterned photoresist mask 60 is provided on hard mask 504 of dielectric-6 material. The hard mask 504 of dielectric-6 material and fill 302 of dielectric-4 material are etched to form openings 502 to a depth which exposes the top field effect transistor (FET) FET channels without yet exposing the bottom FET channels as shown by FIG. 5D. A portion of the tails may also be removed by the etch. This permits a protective layer to be deposited to protect the top FET part and continued etching of the fill 302 of dielectric-4 to access the bottom FET in the stack. FIG. 5E shows a perspective view of the structure 500 without material patterns for clarity of structure boundaries.

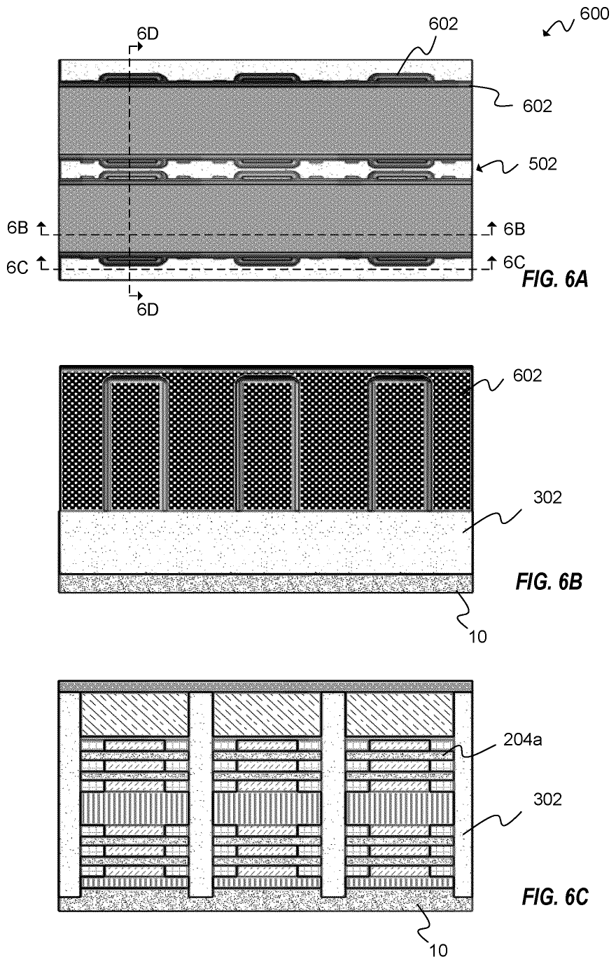

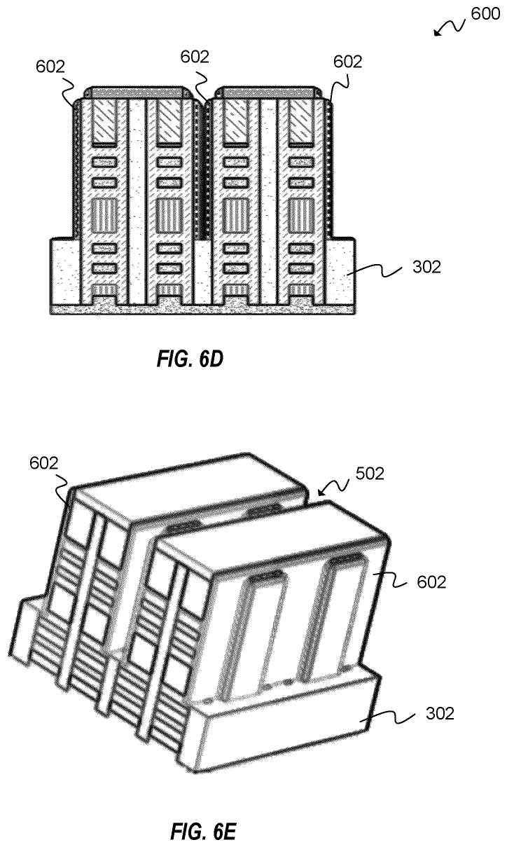

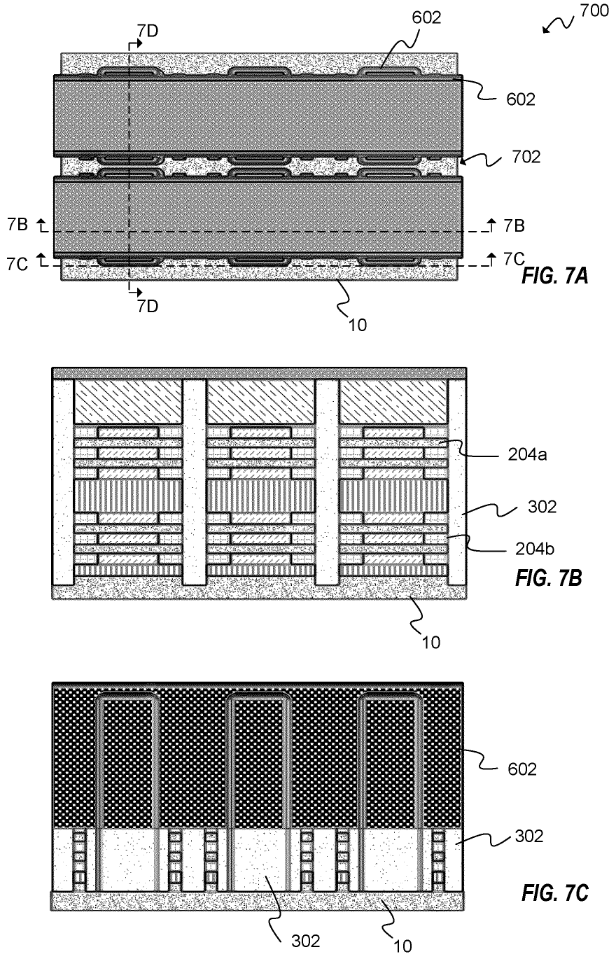

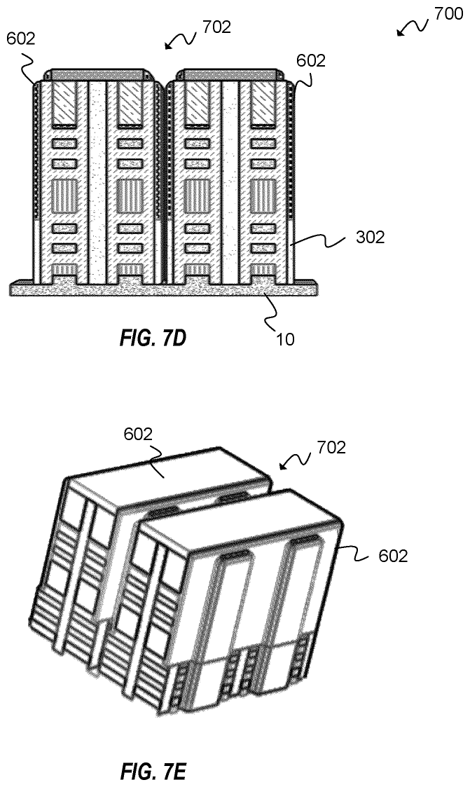

FIGS. 6A, 6B, 6C and 6D show a structure 600 after atomic layer deposition (ALD) of a protective liner 602 of dielectric-1 material in the openings 502. FIG. 6E shows a perspective view of the structure 600 without material patterns for clarity of structure boundaries. FIGS. 7A, 7B, 7C and 7D show a structure 700 after further directionally etching fill 302 of dielectric-4 all the way to Si substrate 10 to provide openings 702. Etch could be controlled and have plenty of room to stop well before reaching Si substrate while being past the lower most nanosheet. The openings 702 provide access to the fill 302 of dielectric-4 that remains on the bottom FET channel region directly below the liner 602 that protects the top FET region. FIG. 7E shows a perspective view of the structure 700 without material patterns for clarity of structure boundaries.

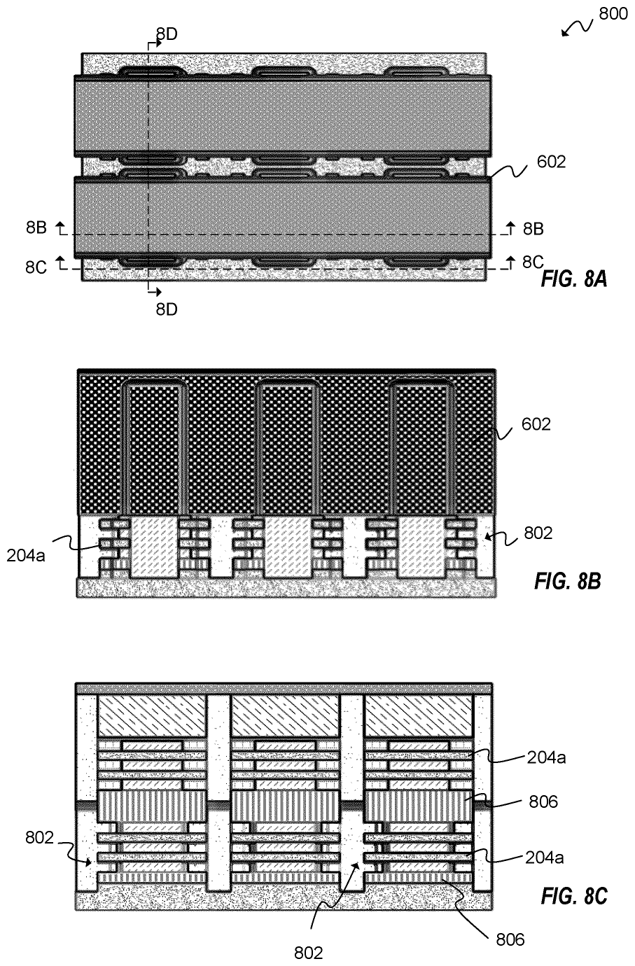

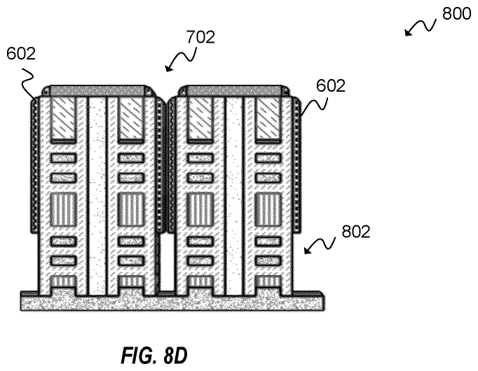

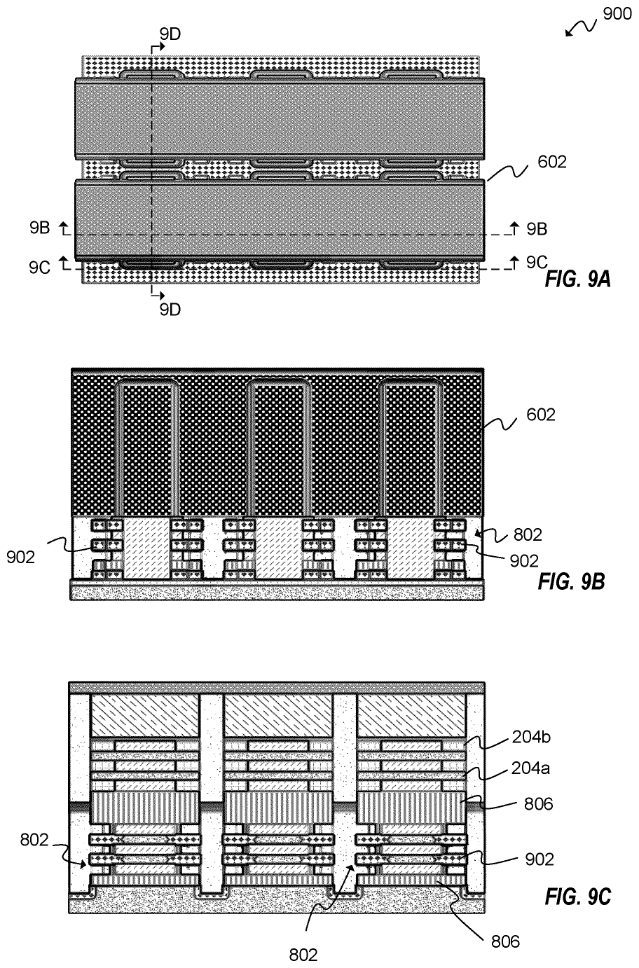

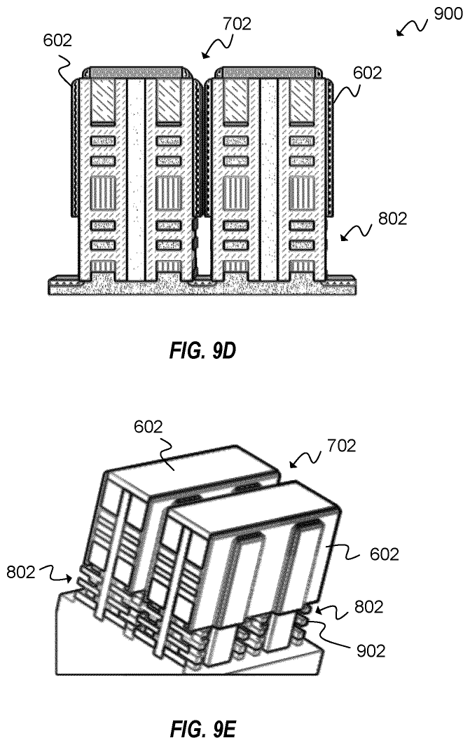

FIGS. 8A, 8B, 8C and 8D show a structure 800 after exposing ends of the nanosheets of the lower FET device. In one example, a wet etch process removes fill 302 of dielectric-4 to expose end surfaces of the nanosheets 204a of the lower device and the remaining SiGe spacer material 204b. Wet etch of the remaining SiGe spacers 204b exposes the nanosheet ends on all sides. The dummy gate helps support the structure and the dummy isolation 806 of SiGe65 material maintains isolation from the substrate 10 and between devices in the stack. FIGS. 9A, 9B and 9C show a structure 900 after doping the nanosheet ends of the lower device. In one example, the nanosheet ends are doped with p+ dopant material to form doped nanosheet ends 902. Dummy isolation layer 806 of SiGe65 material isolates the Si substrate top surface (doped) from the doped nanosheet ends. FIG. 9E shows a perspective view of the structure 900 without material patterns for clarity of structure boundaries.

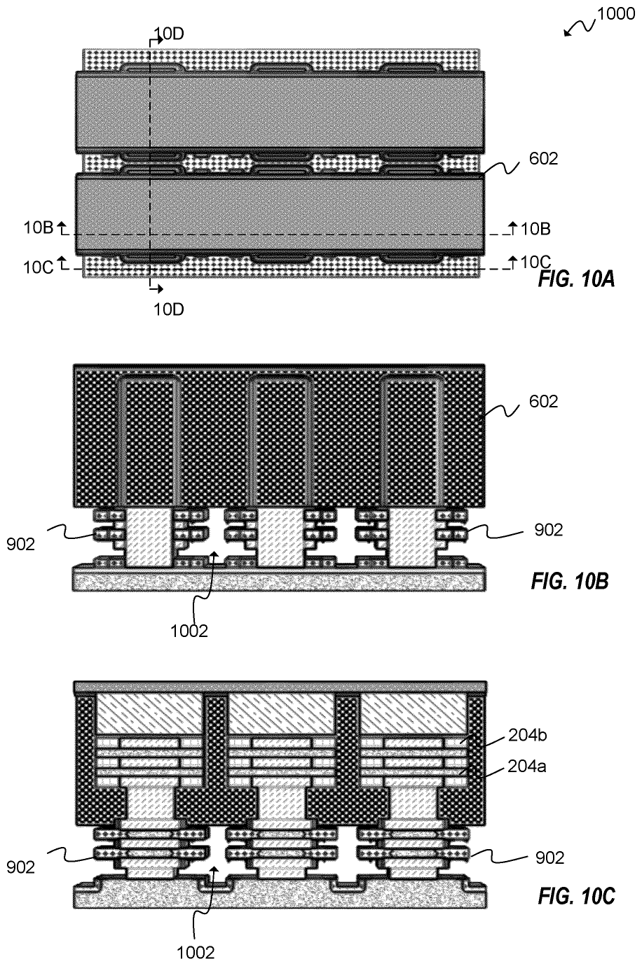

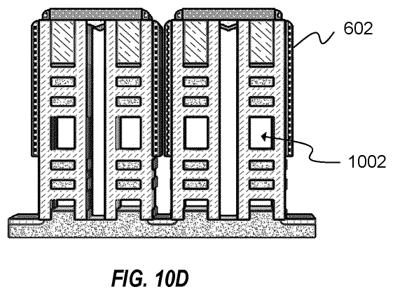

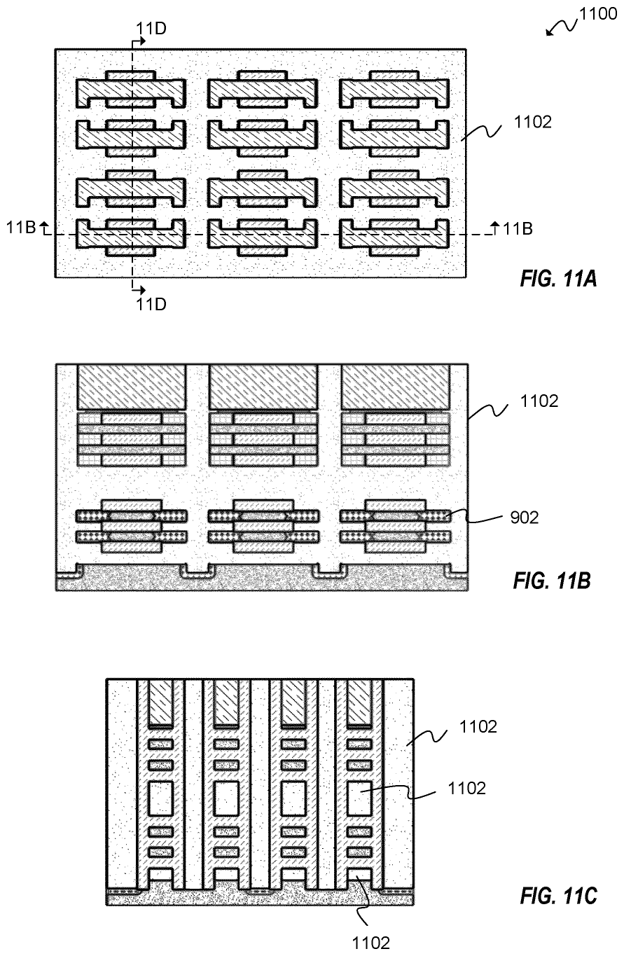

FIGS. 10A, 10B, 10C and 10D show a structure 1000 after removal of dummy isolation 806 between the lower FET device and the substrate 10, and between the FET devices in the stack. In an example process, further wet etch the fill 302 of dielectric-4 is performed to access the dummy isolation 806 of SiGe65 material. Then etch the SiGe65 material to remove the dummy isolation 806. Transistors are well supported by the dummy gate. FIGS. 11A, 11B and 11C show a structure 1100 after removal of the protective liner 602, depositing fill 1102 of dielectric-4 and CMP. Now the fill 1102 of dielectric-4 is isolating nanosheets from each other and from the Si substrate 10.

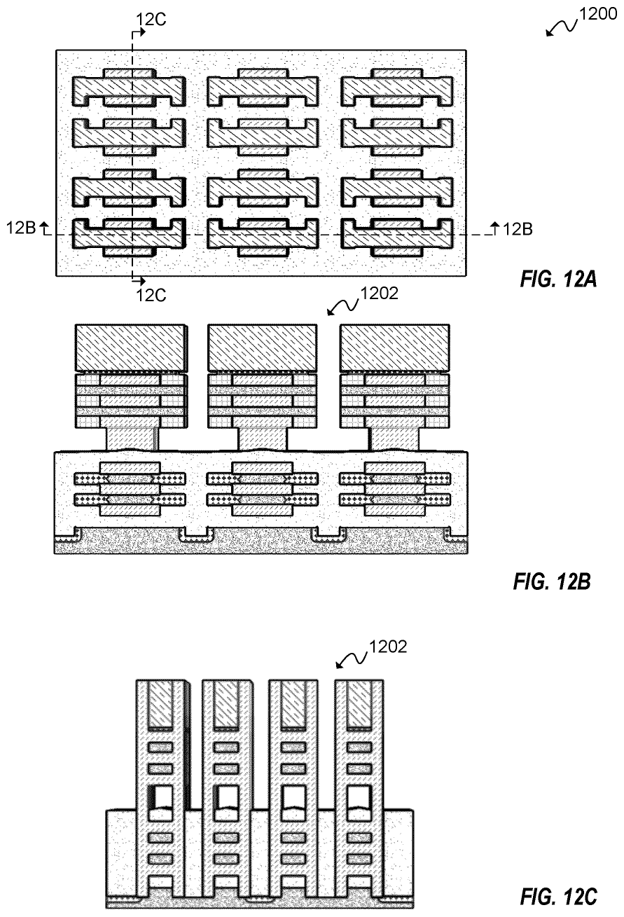

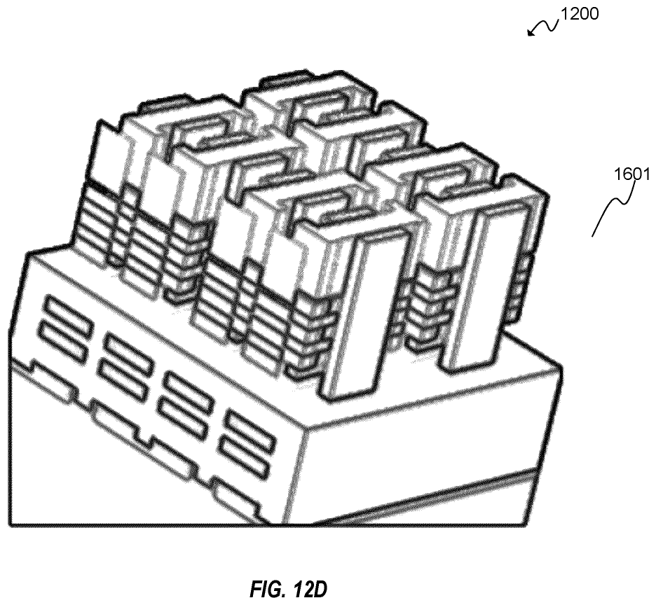

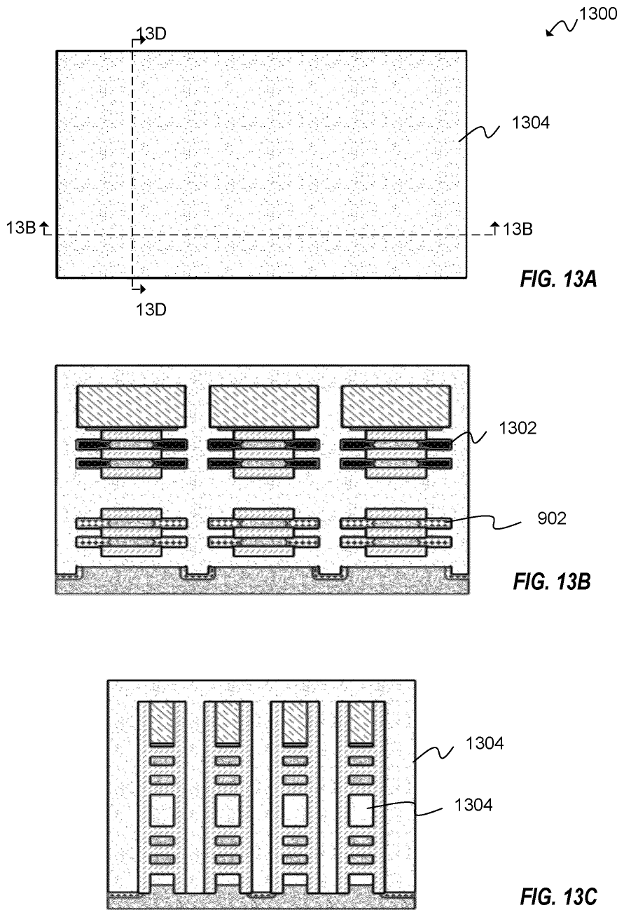

FIGS. 12A, 12B, and 12C show a structure 1200 after opening access to the top FET. For example, the fill 1102 of dielectric-4 is etched to about a mid-point of the stack to form openings 1202 to provide access to the whole top FET. Doping of the top FET is then performed by process steps similar to those described for the bottom FET in FIGS. 8 and 9. In one example, a wet etch process removes fill 1102 of dielectric-4 to expose end surfaces of the nanosheets 204a of the top device and the remaining SiGe spacer material 204b. Wet etch of the remaining SiGe spacers 204b exposes the nanosheet ends on all sides in the top device. The nanosheet ends are then doped with n+ dopant material to form doped nanosheet ends 1302 to provide a complementary FET (CFET) configuration of the bottom and top FETs. Then deposit fill 1304 of dielectric-4 and CMP to provide the structure 1300 of FIGS. 13A, 13B, and 13C which is ready for formation of the Source-Drain (S-D) connections and contacts for the bottom and top devices in the stack.

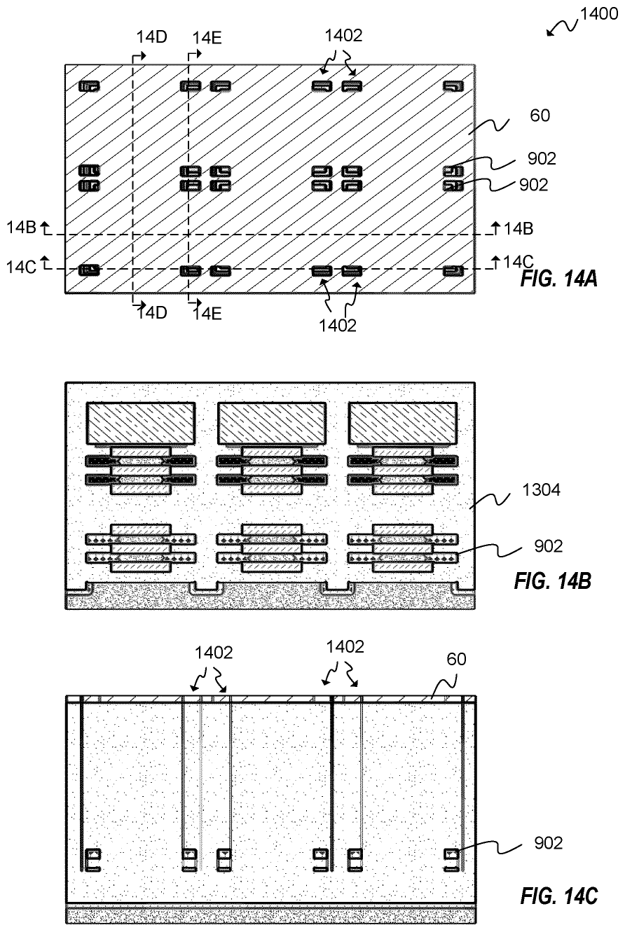

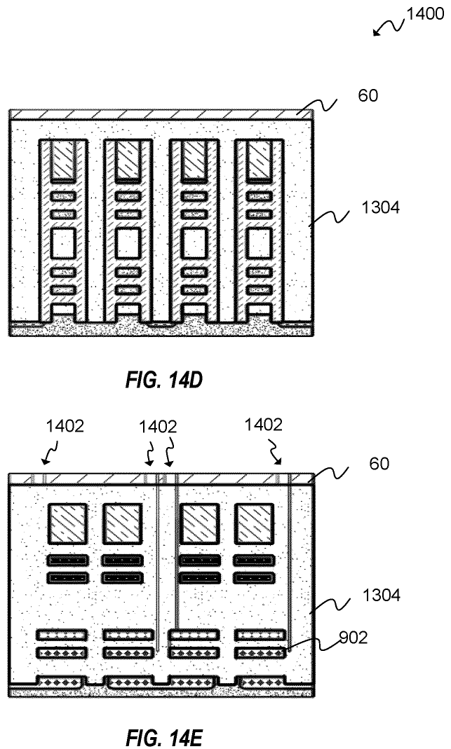

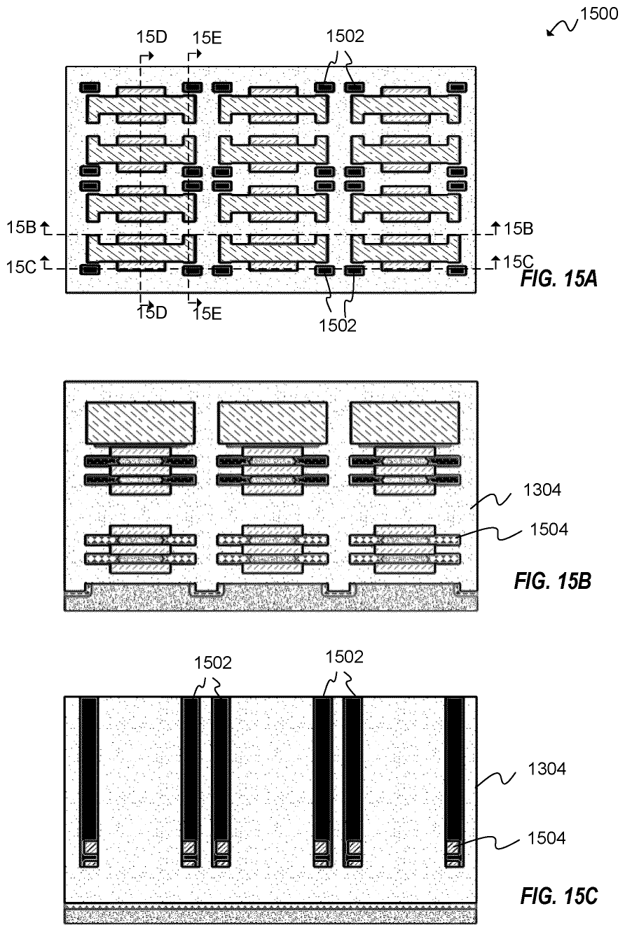

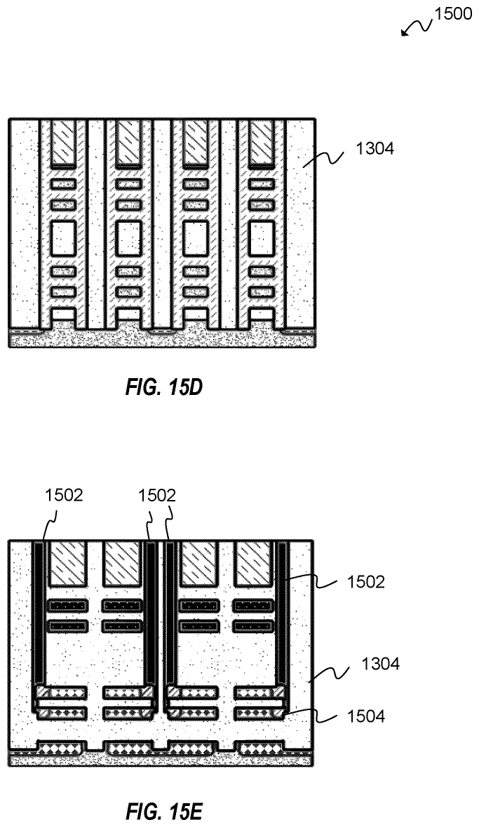

FIGS. 14A, 14B, 14C, 14D and 14E show a structure 1400 after patterning with a bottom FET S-D connector mask. The bottom S-D connector mask 60 is used to etch openings 1402 in fill 1304 of dielectric-4 material with etch stop on doped p-Si nanosheet ends 902. FIGS. 15A, 15B, 15C and 15D show a structure 1500 after forming connections and contacts to the S-D regions of the lower FET. One example process includes depositing fill 1502 of metal-1 material and CMP. Anneal is performed to make lower S-D contacts 1504 of silicide-1 at the junction of metal-1 and p-Si. Two different views from X-axis cross-section shows the metal is extended away from gate contact. That also allows the metal to connect all the nanosheets from 2 sides and bolster the contact.

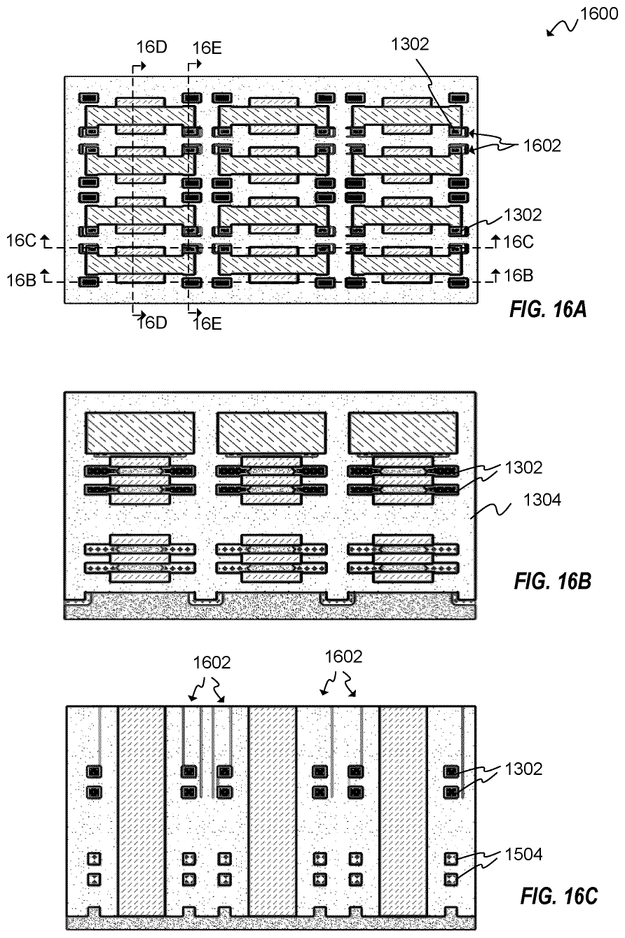

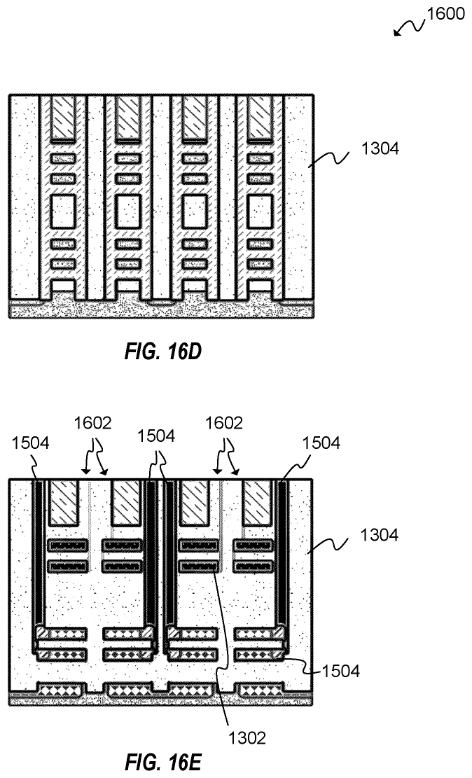

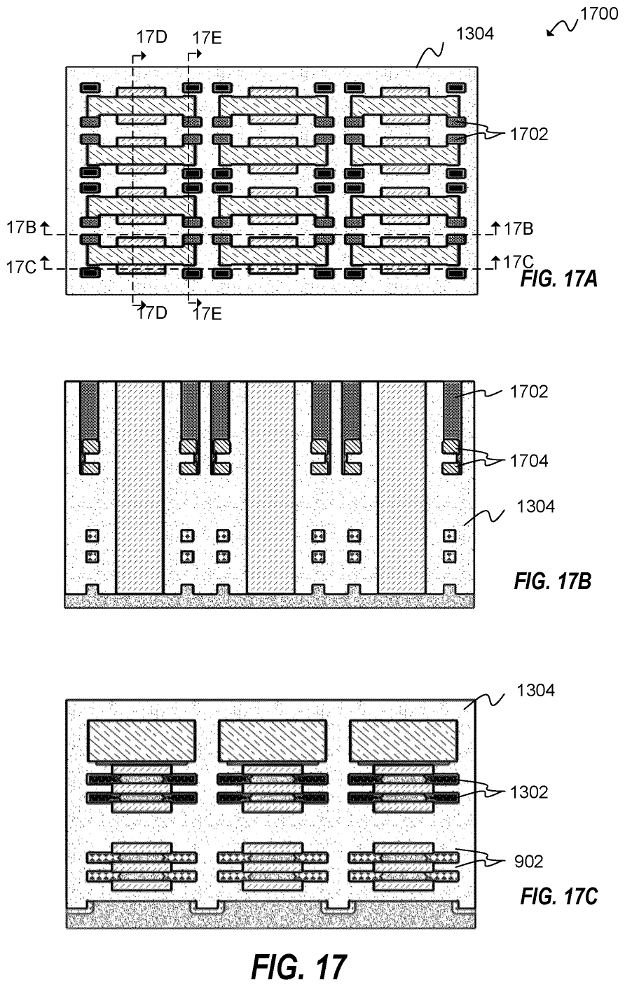

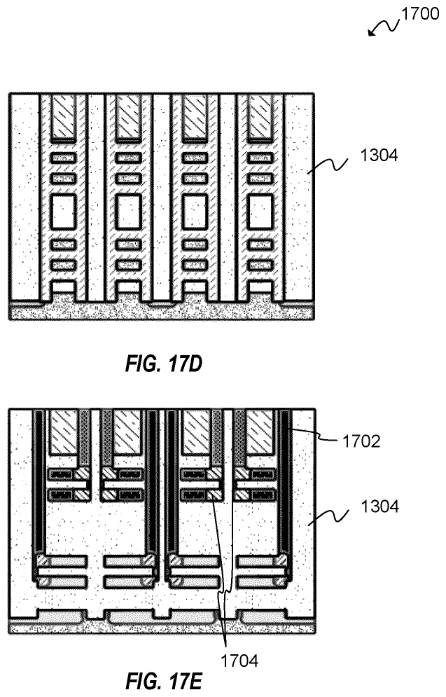

FIGS. 16A, 16B, 16C, 16D and 16E show a structure 1600 after patterning with a top nanosheet S-D connector mask. The top S-D connector mask 60 is used to etch openings 1602 in fill 1304 of dielectric-4 material with etch stop on doped n-Si nanosheet ends 1302. FIGS. 17A, 17B, 17C, 17D and 17E show a structure 1700 after forming connections and contacts to the S-D regions of the upper FET. One example process includes depositing fill 1702 of metal-2 material and CMP. Anneal is performed to make upper S-D contacts 1704 of silicide-2 at the junction of metal-1 and n-Si.

Channel release is then performed, and high-k and gate metal steps are performed independent of S-D contacts.

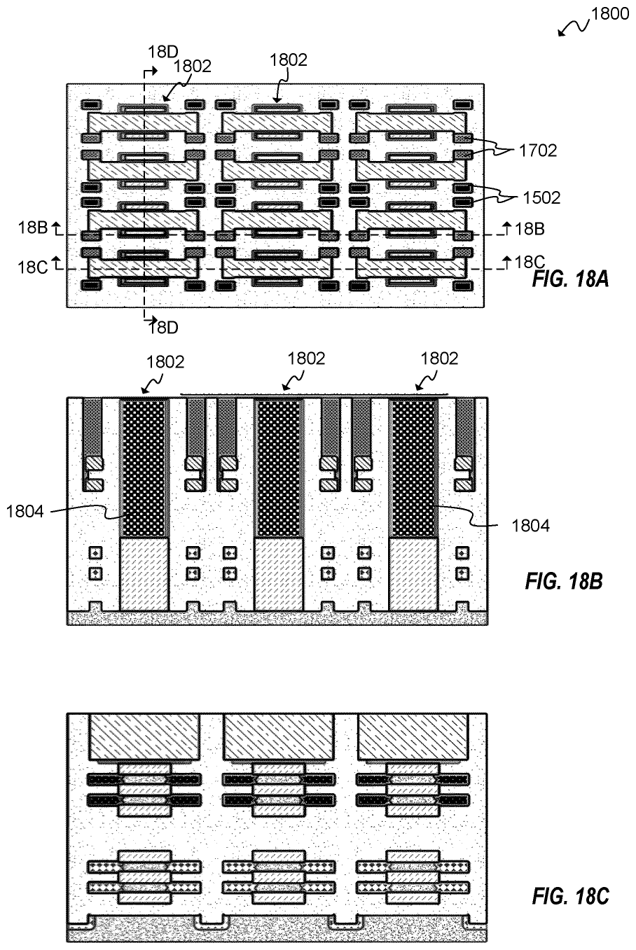

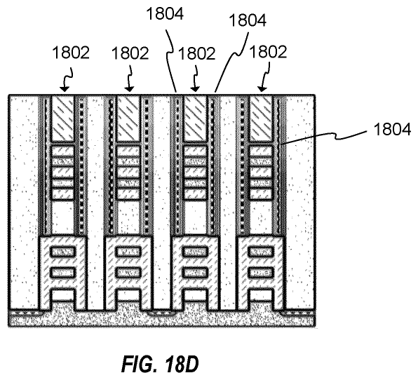

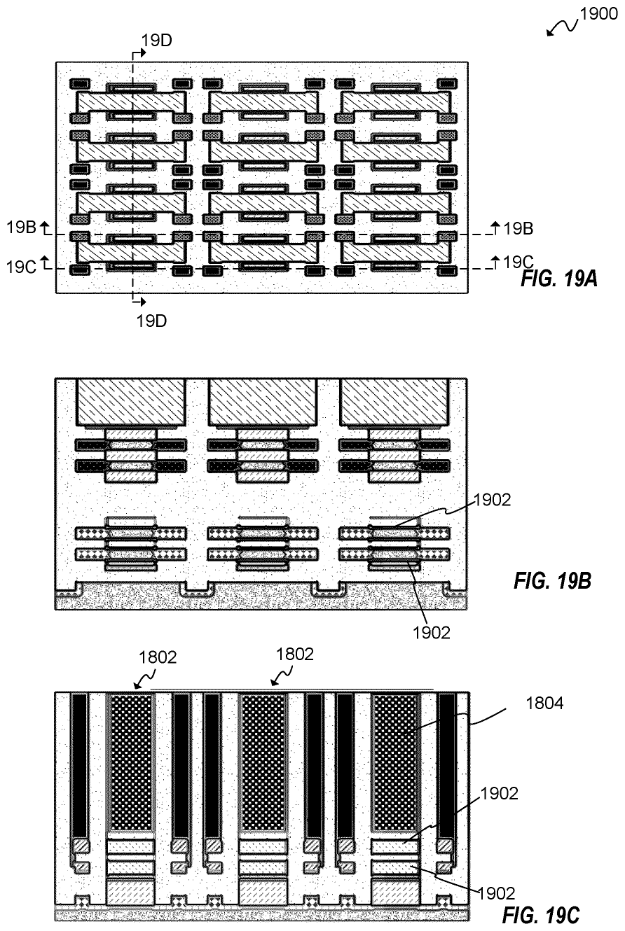

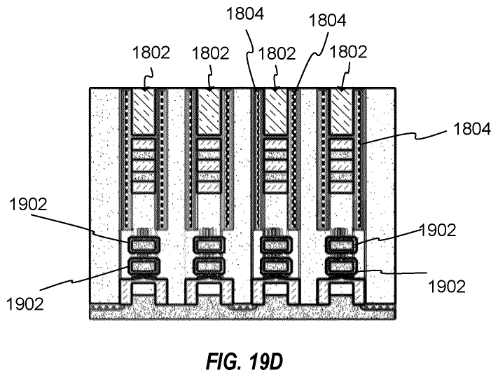

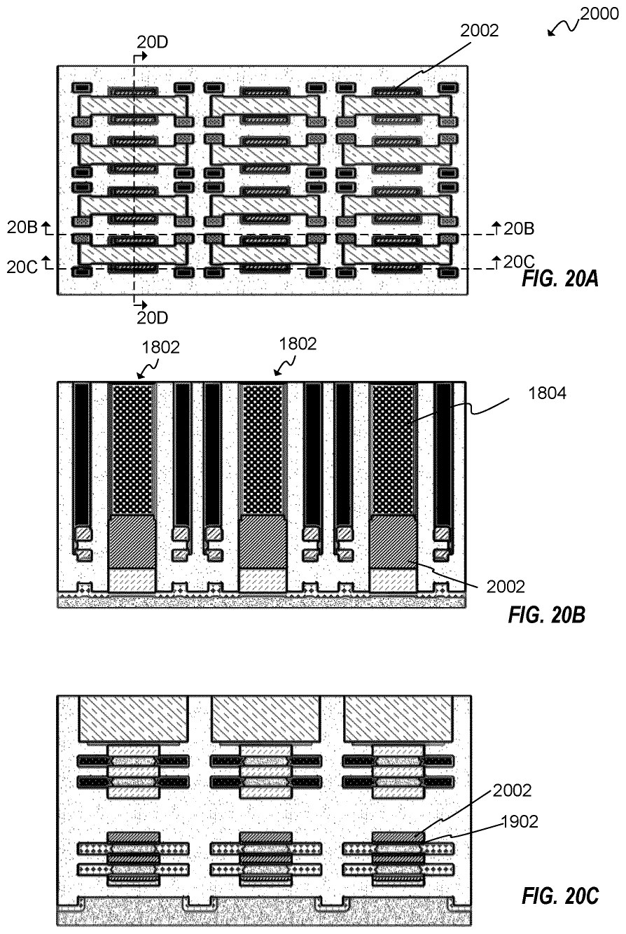

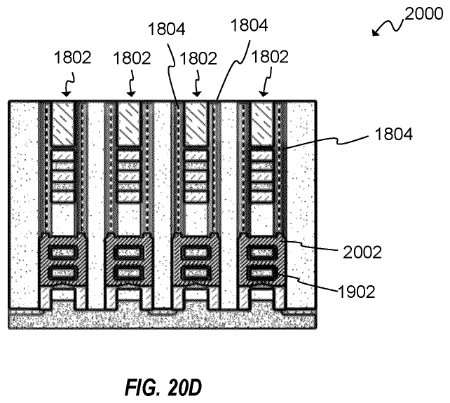

FIGS. 18A, 18B, 18C and 18D show a structure 1800 after providing a liner to protect the top FET device during GAA formation on the lower FET device. In an example, wet etch of dummy gate of dielectric-5 to the middle of the CFET to form openings 1802 for depositing the liner. This self-aligned gate connection opens the nanosheets for gate-all-around. An ALD of liner 1804 of dielectric-1 material is deposited to cover the top FET structure similar to the protective liner described in FIG. 7. Directionally etching dielectric 1 gives access to etch the lower part of the dummy gate of dielectric-5 material. FIGS. 19A, 19B and 19C show a structure 1900 after depositing high-k material 1902 by ALD for example. In one process, wet etch of dielectric-5 removes the dummy gate from the lower device. There is enough room to stop the etch which would keep dielectric-5 as isolation to separate between the lower device nanosheet and substrate 10. Then selective ALD of high-K-1 dielectric on Si of the bottom device (here it is p-Si). Openings 1802 remain for gate metal fill. FIGS. 20A, 20B, 20C and 20D show a structure 2000 after selectively depositing a fill of metal-3 to form gate metal 2002 and CMP.

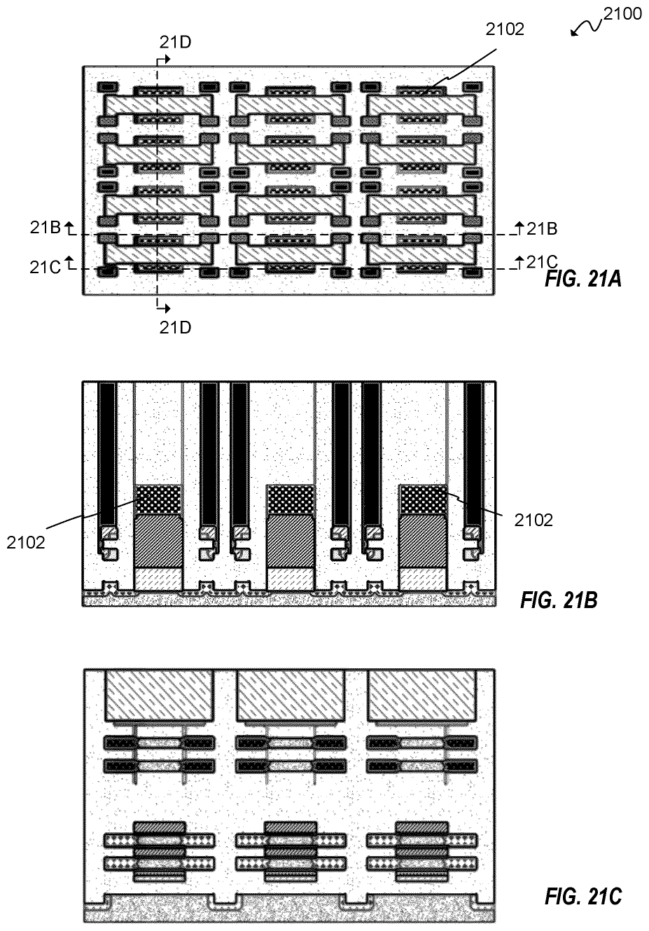

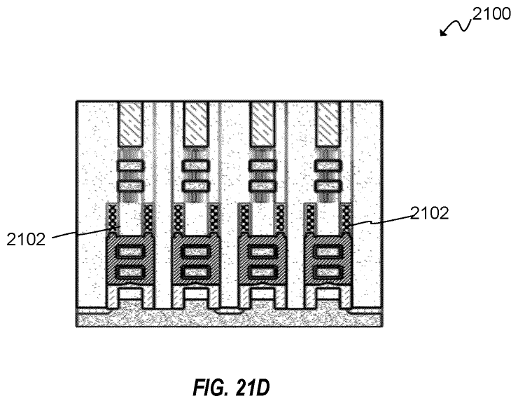

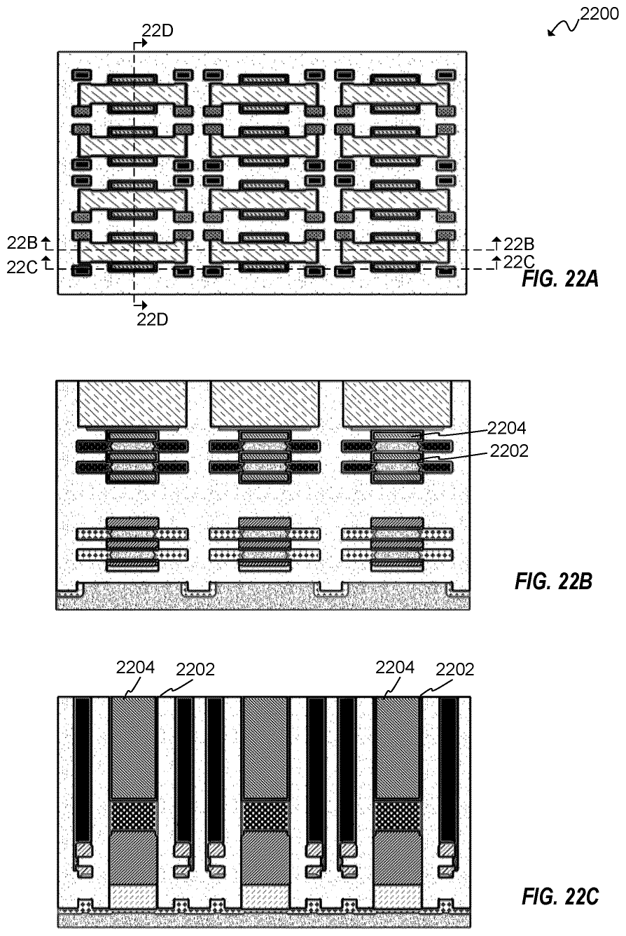

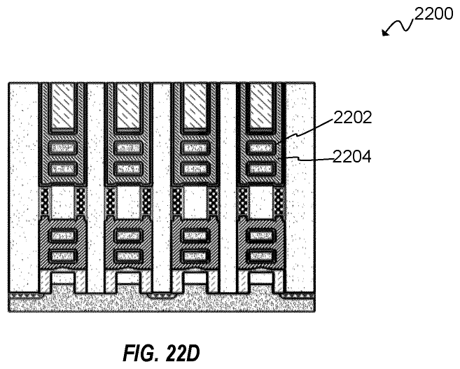

FIGS. 21A, 21B, 21C and 21D show a structure 2100 after depositing a fill liner 2102 of dielectric-1 material. Then directionally etch dielectric 1 until middle of the stack to keep isolation between two gate metals of bottom and top FETs. FIGS. 22A, 22B, 22C and 22D show a structure 2200 after GAA formation in the top FET device. First ALD is used to deposit high-K-2 dielectric, and then a fill of metal-4 is deposited and CMP is performed.

In accordance with embodiments herein, S-D contacts are offset from the GAA contact to provide for lower capacitance. Further, the active area of S-D is contact reduced for lower capacitance. The complementary FET is formed by separate doping for bottom and top

FETs, separate forming of S-D contacts for bottom and top FET, and separate forming of GAA contacts for bottom and top FETs.

Techniques disclosed herein include methods and designs for a complex shaped channel structure transistor, for example with a main portion and tail portions. Any deposited channel can be used including conductive oxide (semi-conductive oxide), 2D material, and large grain semiconductors. The electron or hole flow in the channel, flows from one source-drain (S-D) end, through a first tail portion into the main portion of the channel, into the second tail portion and to a second S-D end.

The semiconductor layers may be made from semiconductor materials such as Si, Ge, SiGe, GaAs, InAs, InP, semiconductive behaving oxide (e.g. In₂O₃, SnO₂, InGaZnO, and ZnO, SnO), 2D material (e.g. WS₂. WSe₂, Wte₂, MoS₂, MoSe₂, MoTe₂, HfS₂, ZrS₂, TiS₂, GaSe, InSe, phosphorene, HfSe₂, ZrSe₂, HfZrSe₂, etc.) or any other suitable semiconductor material in monocrystalline and/or polycrystalline form. Further, the S-D regions may be doped with either p-type or n-type dopants at various doping concentration levels. The p-type dopant may be boron and the n-type dopant may be phosphorus or arsenic, however other suitable dopant materials may be used. Various techniques may be used to provide a strained channel material to improve carrier mobility, for example.

The doped S-D regions may also be made from any semiconductor material in monocrystalline or polycrystalline form and doped with either p-type or n-type dopants at various doping concentration levels. Various S-D contact engineering techniques known in the semiconductor fabrication art may be employed in the design and formation of S-D regions. For example, the S-D regions may include S-D extensions.

Insulation and dielectric layers may be implemented as a dielectric material such as SiO, SIN, SiON, SiC, SiOC, SiCN, SiOCN, the like, or a combination thereof. These structures may also be implemented as high-k dielectrics. The same or different dielectric materials can be used for these structures. Device contacts, connections vias and the like may be made of any conductive material, such as a doped polysilicon material or a metal such as W, Co, Ru, Cu, Al, the like, or combinations thereof. The same or different conductor materials can be used for these structures.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

What is claimed is:

1. A method of fabricating a semiconductor device, comprising:
forming a patterned stack of layers including at least one lower active layer for forming a lower transistor and at least one upper active layer for forming an upper transistor stacked on the lower transistor;
forming a dummy gate surrounding a gate portion of each of the lower active layers and each of the upper active layers in the patterned stack;
doping source-drain portions of the lower active layers and the upper active layers;
forming source-drain connections to doped source-drain portions of the lower active layers and the upper active layers; and
replacing the dummy gate of the lower active layers and the upper active layers with a gate-all-around structure to form the lower transistor and the upper transistor.

2. The method of claim 1, wherein the forming a patterned stack comprises forming a stack of alternating layers of active material and sacrificial material.

3. The method of claim 2, wherein the forming a stack comprises forming at least two lower active layers for forming a multichannel lower transistor and at least two upper active layers for forming a multichannel upper transistor.

4. The method of claim 2, wherein the stack of alternating layers comprises:
a silicon layer for each layer of active material; and
a silicon germanium layer for each layer of sacrificial material.

5. The method of claim 4, wherein the forming a dummy gate comprises:
removing sacrificial material from above and below the gate portion of each of the lower active layers and each of the upper active layers in the patterned stack; and
replacing the removed sacrificial material with dummy gate material.

6. The method of claim 2, wherein the doping source-drain portions comprises doping the lower active layers with a first doping material and doping the upper active layers with a second doping material, the first and second doping materials being different dopants selected from n-type dopants and p-type dopants such that the lower transistor and the upper transistor are complementary transistors.

7. The method of claim 6, further comprising:
forming a protective liner on the upper active layers;
exposing the source-drain portions of the lower active layers, and
doping the source-drain portions of the lower active layers with the first doping material while the upper active layers are protected by the protective liner.

8. The method of claim 7, further comprising:
after doping the source-drain portions of the lower active layers, forming a protective fill on the lower active layers;
exposing the source-drain portions of the upper active layers, and
doping the source-drain portions of the upper active layers with the second doping material while the lower active layers are protected by the protective fill.

9. The method of claim 8, further comprising forming a source-drain isolation structure between the lower active layers and the upper active layers after doping the source-drain portions of the lower active layers and before doping the source-drain portions of the upper active layers.

10. The method of claim 1, wherein the forming source-drain connections comprises:
etching an opening to expose a contact part of each of the doped source-drain portions of the lower active layers and the upper active layers; and
filling each opening with a connection metal fill such that each metal fill forms a contact interface where the metal fill contacts a respective contact part of the doped source-drain portions.

11. The method of claim 10, further comprising annealing each interface portion to form a silicide contact between each metal fill and a respective doped source-drain portion.

12. The method of claim 1, wherein the forming source-drain connections comprises forming lower source-drain connections to the lower active layers before forming upper source-drain connections to the upper active layers.

13. The method of claim 1, wherein the replacing the dummy gate comprises:
etching the dummy gate material to expose a respective gate portion of each of the lower active layers and the upper active layers;
selectively depositing a gate dielectric layer on each exposed gate portion; and
forming a gate metal layer on each gate dielectric layer.

14. The method of claim 13, further comprising:
forming a protective liner on the upper active layers;
exposing the gate portions of the lower active layers; and
forming the lower GAA structure around the exposed lower active layers while the upper active layers are protected by the protective liner.

15. The method of claim 14, further comprising:
after forming the lower GAA structure on the gate portions of the lower active layers, forming a protective fill on the lower active layers;
exposing the gate portions of the upper active layers, and
forming the upper GAA structure around the exposed upper active layers while the lower active layers are protected by the protective liner.

16. The method of claim 15, further comprising forming a gate isolation structure between the lower active layers and the upper active layers after forming the GAA structure around the gate portions of the lower active layers and before forming the GAA structure on the gate portions of the upper active layers.

17. A semiconductor device comprising:
a substrate comprising a working surface; and
stacked complementary transistors formed in the substrate, each transistor comprising:
a complex channel structure which is horizontally arranged with respect to the working surface, the complex channel structure comprising a main portion extending in a main direction along the working surface, and tail portions each connected to a respective end of the main portion and extending along the working surface in a tail direction which is different from the main direction, a distal end of each tail including a source S-D end such that the S-D ends are offset from the main portion of the complex channel structure,
a gate all around (GAA) structure formed around only the main portion of the complex channel structure between the tail portions, and
S-D contacts formed on respective S-D ends of the complex channel structure such that the S-D contacts are offset from the GAA structure.

18. The semiconductor device of claim 17 wherein each tail portion extends along a direction substantially perpendicular to the main portion.

19. The semiconductor device of claim 17 wherein the S/D contacts comprise metal and silicide.

20. The semiconductor device of claim 17 wherein the complex channel structure is U-shaped in a plane parallel to the working surface of the substrate.
